(19) United States
(12) Patent Application Publication
(10) Pub. No.: US 2019/0305004 A1
(43) Pub. Date: Oct. 3, 2019

(54) DISPLAY SCREEN AND ELECTRONIC DEVICE HAVING THE SAME

(71) Applicant: Lenovo (Beijing) Co., Ltd., Beijing (CN)

(72) Inventors: Youze LI, Beijing (CN); Jun SHI, Beijing (CN); Xiangyang LI, Beijing (CN); Yong TAN, Beijing (CN); Yiping FENG, Beijing (CN)

(21) Appl. No.: 16/367,980

(22) Filed: Mar. 28, 2019

(30) Foreign Application Priority Data
Mar. 30, 2018 (CN) 201810278910.4

(51) Int. Cl. H01L 27/12; G09F 9/30; G09G 3/20

(52) U.S. Cl. CPC H01L 27/124; G09G 2300/0452; G09G 3/2003; G09F 9/30

(57) ABSTRACT

A display screen includes a plurality of display pixels. Each display pixel includes at least one color film unit. The plurality of display pixels include a plurality of first-type display pixels and one or more second-type display pixels. A color film area of the color film unit of a second-type display pixel is different from a color film area of the color film unit of a first-type display pixel.

### CROSS-REFERENCE TO RELATED APPLICATION

This application claims priority to Chinese Application No. 201810278910.4, filed on Mar. 30, 2018, the entire contents of which are incorporated herein by reference.

### FIELD OF THE DISCLOSURE

The present disclosure relates to display technology and, more particularly, to a display screen and an electronic device having the same.

### BACKGROUND

Currently, to pursue the aesthetic appearance of electronic devices, the display screens (e.g., touch screens) of most electronic devices are generally no longer designed as rectangles, but are designed to have other shapes, such as the rectangles with rounded vertexes. However, because the shape of pixels is unchangeable, the pixels located at the vertexes will appear as a zig-zag shape. Therefore, when the screen is powered on, the zig-zag shape will appear, thereby affecting the overall display effect.

The disclosed methods and systems are directed to solve one or more problems set forth above and other problems.

### SUMMARY

In accordance with the disclosure, there is provided a display screen including a plurality of display pixels. Each display pixel includes at least one color film unit. The plurality of display pixels include a plurality of first-type display pixels and one or more second-type display pixels. A color film area of the color film unit of a second-type display pixel is different from a color film area of the color film unit of a first-type display pixel.

Also in accordance with the disclosure, there is provided an electronic device including a body and a display screen. The display screen includes a plurality of display pixels. Each display pixel includes at least one color film unit. The plurality of display pixels include a plurality of first-type display pixels and one or more second-type display pixels. A color film area of the color film unit of a second-type display pixel is different from a color film area of the color film unit of a first-type display pixel.

### BRIEF DESCRIPTION OF THE DRAWINGS

FIG. 1 schematically shows a display effect at a curved edge of a display screen;

FIG. 2 is a partial structural view of a display screen;

FIG. 3 is a structural diagram of a partial display screen according to the present disclosure;

FIG. 4 schematically shows a display effect of a partial display screen according to the present disclosure;

FIG. 5 is a structural diagram of another partial display screen according to the present disclosure; and

FIG. 6 shows an electronic device according to the present disclosure.

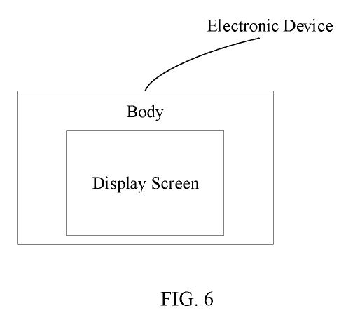

### DETAILED DESCRIPTION

Hereinafter, embodiments of the present disclosure are described with reference to the drawings. Various modifications to the embodiments will be apparent to those skilled in the art. The described embodiments are merely example of embodiments of the present disclosure, but not all of embodiments of the present disclosure. Other embodiments obtained based on the disclosed embodiments by those skilled in the art without creative efforts are intended to be within the scope of the present disclosure.

The embodiments of the present disclosure are described with reference to the drawings that are included in the specification and form a part of the specification. Features of the present disclosure will become apparent from the following description of the non-limited exemplary embodiments with reference to the drawings.

Although the present disclosure will be described with reference to some exemplary embodiments, those skilled in the art can implement many other equivalents of the present disclosure, which have the features described in the claims and are within the protection scope of the claims. The above and other aspects, features and advantages of the present disclosure will become apparent from the details described hereinafter with reference to the drawings.

However, it is appreciated that the disclosed embodiments are merely examples of the present disclosure, which can be implemented in various ways. The well-known and/or repeated functions and structures will not be described in detail to avoid that unnecessary or reductant details may obscure the present disclosure. Therefore, the structural and functional details disclosed herein are not intended to limit the present disclosure, but are merely a basis of the claims, and configured to teach those skilled in the art to use the present disclosure in any suitable and detailed structure.

The terms “in one embodiment,” “in another embodiment,” “in some embodiments,” or “in some other embodiments” refer to one or more of the same or different embodiments in accordance with the present disclosure.

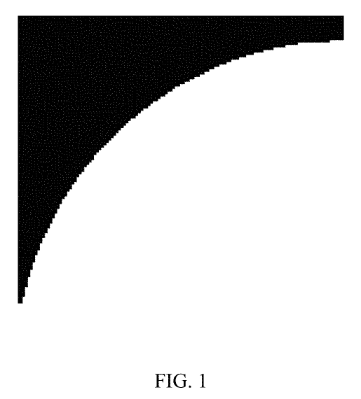

FIG. 1 schematically shows a display effect at a curved edge of a display screen.

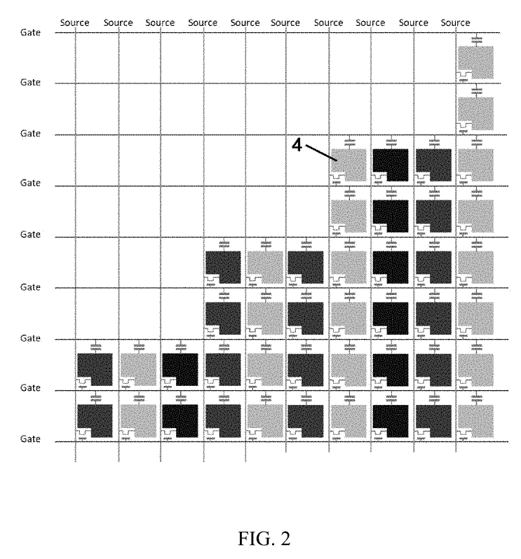

FIG. 2 is a partial structural view of a display screen.

To satisfy the users' pursuit of the aesthetic appearance of the electronic device, display screens (e.g., touch screens) of most electronic devices are generally no longer designed as rectangles, but are designed to have other shapes, such as the rectangles with rounded vertexes. However, as shown in FIGS. 1 and 2, because the shape of pixels is unchangeable, the pixels located at the vertexes will appear as a zig-zag shape. Therefore, when the screen is powered on, the zig-zag shape will appear, thereby affecting the overall display effect.

In order to solve the above-described technical problems, two solutions have been developed.

1. An optimization algorithm for the zig-zag is added inside a driver chip of the display device. However, the drawbacks are 1) The power consumption of the driver chip is increased; and 2) The display device is generally matched with the driver chips from multiple manufacturers. The driver chips produced by different manufacturers have different optimization algorithms for zig-zag, resulting in the uneven display effects.

2. The optimization algorithm for the zig-zag is added to a driver platform of the display device. However, the drawbacks are 1) The driver platform needs to add a layer of blur mask for the zig-zag on all the display images, therefore, a resident application corresponding to the mask needs to be added, thereby increasing the power consumption of the driver platform; and 2) Different driver platforms have different optimization capabilities, resulting in the uneven display effects.

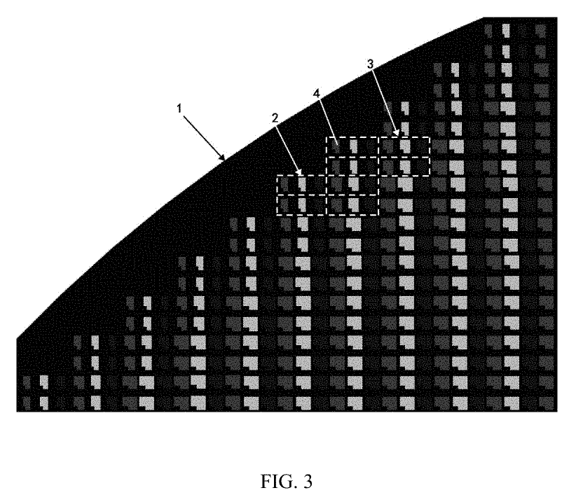

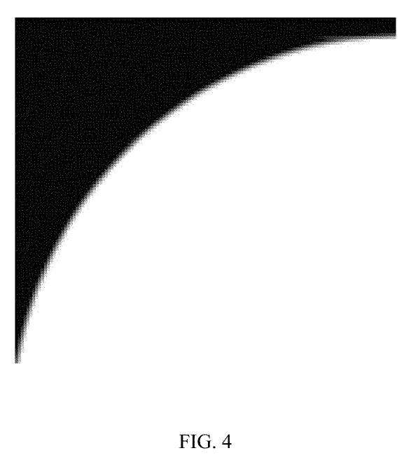

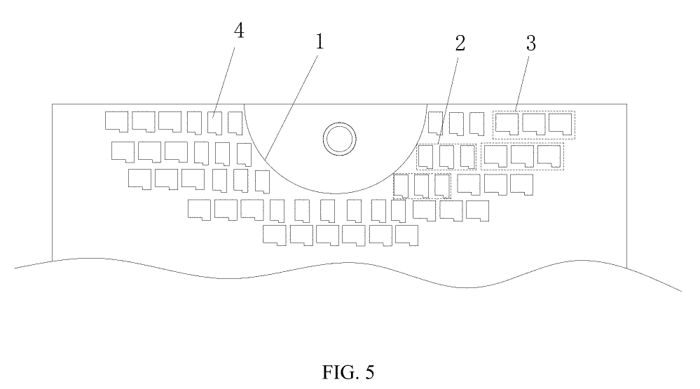

FIG. 3 is a structural diagram of a partial display screen consistent with the present disclosure. FIG. 4 schematically shows a display effect of a partial display screen consistent with the present disclosure. FIG. 5 is a structural diagram of another partial display screen consistent with the present disclosure.

As shown in FIG. 3, the display screen includes a plurality of display pixels. Each display pixel including at least one color film unit. As shown in FIG. 3, reference numerals 1, 2, 3, and 4 respectively represent the curved edge, a first display pixel, a second display pixel, and a color film unit.

The plurality of display pixels include a plurality of first type of display pixels, e.g., the first display pixel 2, and at least one second type of display pixel, e.g., the second display pixel 3. A color film area of the color film unit 4 of the second type of display pixel is different from the color film area of the color film unit 4 of the first type of display pixel. The display pixels corresponding to the curved edge of the display screen among the plurality of the display pixels can be the second type of display pixels and other pixels can be the first type of display pixels.

The display pixel includes a plurality of color film units 4 having different colors. As shown in FIGS. 3 and 5, a dotted line box shows one display pixel, and a size of the color film area of the color film unit 4 can determine a brightness of a corresponding portion of the display screen. Since the plurality of display pixels in the display screen include two types of display pixels having different color film areas, the display effect of the display screen can be different from the display effect of an ordinary display screen. The user can arrange a position distribution of the two types of display pixels, according to the actual requirements, such that the position distribution can be matched with, for example, an overall structure or shape of the display screen, thereby improving the overall display effect of the display screen.

In some embodiments, at least a portion of an edge of the display screen can have a curved shape. For example, the display screen can have an approximately rectangular shape as a whole, and each of the vertexes can have a circular-arc shape. As another example, the display screen can have a circular shape as a whole, or can be a “Notch full screen” currently popular in the market, where a notch is designed for reserving a position for, for example, a camera on the electronic device. The edge of the notch may have the curved shape as a whole, or only a portion of the edge may have the curved shape. At least a portion of the edge of the display may also have a diagonal shape or the like. The display pixels corresponding to the curved edge 1 of the display screen among the plurality of display pixels are the second type of display pixels, and the first type of display pixels may be located in the middle area of the display screen, i.e., located at the area of an inner side of the second type of display pixels.

Since the shape of the display pixels does not match the shape of the curved edge 1, the portion corresponding to the curved edge 1 in the display screen cannot be completely filled, such that when the display pixels at the corresponding curved edge 1 are displayed in a high brightness, the user can easily find that an image displayed at the curved edge 1 has the zig-zag shape, and the display effect will not be good, as shown in FIGS. 1 and 2.

Consistent with the present disclosure, to avoid a phenomenon described above, the display brightness of the display pixels at the curved edge 1 can be reduced to blur the display effect of the portion, thereby avoiding the occurrence of the above phenomenon. Therefore, in some embodiments, the second type of display pixels can be configured to have the color film area of the color film unit 4 that is smaller than the color film area of the color film unit 4 of the first type of display pixels, and the second type of display pixels can be arranged at a position corresponding to the curved edge 1 to reduce the brightness at the position to achieve the blurring effect, as shown in FIG. 4.

The above-described method does not need to change the power consumption of the driver chip, and does not need to make major changes and processing on the display screen or add any resident application, such that the technical problem can be easily solved and the operation can be very simple and convenient.

The second type of display pixels 3 may be arranged at different positions of the display screen, or the position of the second display pixel 3 may be changeable. Details will be described below.

In some embodiments, the display pixels that are closest to the curved edge 1 among the plurality of display pixels can be defined as the second type of display pixels. That is, the display pixels closest to the curved edge 1 can be the second type of display pixels.

In some embodiments, the plurality of display pixels can be arranged in an array, for example, the plurality of display pixels can be arranged in a plurality of rows (or a plurality of columns).

The second type of display pixels can be the display pixels having the shortest distance from the curve edge 1 among at least one row of display pixels corresponding to the curved edge 1, or the second type of display pixels can be the display pixels having the shortest distance from the curved edge 1 among at least one column of display pixels corresponding to the curved edge 1.

For example, the edge of the vertexes of the display screen can be the curved edge 1 that has multiple rows (or multiple columns) of display pixels. No matter whether the display pixels are multiple rows or multiple columns, a first display pixel toward an end of the curved edge 1 is closest to the curved edge 1, such that it is the second type of display pixel.

For another example, as shown in FIG. 5, a central portion of the edge of the display screen is recessed to form the circular-arc shape notch, and the notch forms the curved edge 1 as a whole. The multiple rows of display pixels and/or one or more columns of display pixels corresponding to the notch can be determined according to the shape and size of the notch.

Among the multiple rows of display pixels and/or one or more columns of display pixels, the display pixels approximating to an outer edge of the notch (i.e., the curved edge 1) are closest to the curved edge 1. That is, the plurality of display pixels arranged to be consistent with the shape of the notch and approximately covering the outer edge of the notch can be the second type of display pixels.

In some embodiments, it is not intended to limit that the second type of display pixels, e.g., the display pixels closest to the curved edge 1, includes the pixel at a first position, a last position, or a fixed position in each row or column of display pixels. Since the shape of the display screen for different electronic devices may be different, the position and size of the curved edge 1 may also be different, such that the position of the second type of display pixel can be different but not limited to the fixed position of the display screen. In some embodiments, the position and number of the second type of display pixels arranged at the display screen can be correspondingly changed according to the position of the curved edge 1 arranged at the display screen and the length of the curved edge 1. That is, as long as the display screen has the curved edge 1, the display pixels respectively closest to each point on the curved edge 1 can be the second type of display pixels.

In some embodiments, the display pixels in an edge area corresponding to the curved edge 1 among the plurality of display pixels can be defined as the second type of display pixels.

In some embodiments, the plurality of display pixels can be also arranged in the array, for example, having a plurality of rows (or a plurality of columns) of display pixels.

For example, the display pixels in the edge area can include the first display pixel 2 and the second display pixel 3.

The first display pixel 2 can be the display pixel having the shortest distance from the curved edge 1 among the at least one row of display pixels corresponding to the curved edge 1.

The second display pixel 3 can be a display pixel adjacent to the first display pixel 2 among the at least one row of display pixels.

In some other embodiments, the display pixels in the edge area can include the first display pixel 2 and the second display pixel 3.

The first display pixel 2 can be the display pixel having the shortest distance from the curved edge 1 among the at least one column of display pixels corresponding to the curved edge 1.

The second display pixel 3 can be the display pixel adjacent to the first display pixel 2 among the at least one column of display pixels.

In some embodiments, as shown in FIGS. 3 and 5, the first display pixel 2 can be the second type of display pixel, e.g., one of the display pixels that are respectively closest to each point on the curved edge 1 among the plurality of rows (or the plurality of columns) of display pixels. A plurality of first display pixels 2 can be arranged to form a linear region that approximately covers or locates on the curved edge 1, the shape of the linear region can be the same as and proportional to the shape of the curved edge 1.

The second display pixel 3 can be the display pixel adjacent to the first display pixel 2 in the row (or column) where the first display pixel 2 is located. For example, the second display pixel 3 has approximately a one-to-one correspondence with the first display pixel 2, and almost each of the plurality of the first display pixels 2 has the corresponding second display pixel 3 (except for the row or column of display pixels having only the first display pixel 2). A plurality of second display pixels 3 can be also arranged to form the linear region, which covers or locates on the linear region formed by the plurality of the first display pixels 2. That is, the linear region formed by the plurality of the second display pixels 3 can be used to thicken and enlarge the linear region formed by the plurality of the first display pixels 2, and the two linear regions cooperatively form the edge area described above.

A blurring display effect at the curved edge 1 can be enhanced, and can completely prevent the user to perceive that the display at the corresponding curved edge 1 in the display screen has the zig-zag shape, thereby further improving the user's visual experience.

The edge area can be different. For example, a thickness of the edge area in each direction which is determined bythe number display pixels are included in each direction can be different, and may be determined according to the actual situation of the display screen. For example, when the display screen is large and the curved edge 1 is also large, the thickness of the edge area in each direction can be appropriately increased. For example, the third display pixel adjacent to the second display pixel 3 in the row or column where the second display pixel 3 is located can be also included in the edge area, and the display brightness of the third display pixel or the like can be reduced.

As shown in FIGS. 3 and 5, the color film area of the color filter unit 4 of the first display pixel 2 and the color film area of the color filter unit 4 of the second display pixel 3 may be same or different. For example, the color film area of the color filter unit 4 of the first display pixel 2 can be set to be smaller than the color film area of the color filter unit 4 of the second display pixel 3, such that the blurring effect on the edge area can gradually increase in a direction near the curved edge 1, exhibiting a progressive blurring effect. When the user views the content displayed on the display screen, the display of the image near the curved edge 1 can be gradually blurred, providing a buffer space for the user's visual response, such that the user can be more adapted to the blur, and the viewing effect of the user can be improved.

As shown in FIG. 3, any display pixel in the display area other than the edge area of the display screen is the first type of display pixel. The color film area of the color film unit 4 of the first type of display pixel can be fixed, for example, a maximum area of the color film or the maximum area of the adjacent color film, or the like, to ensure a high-definition display of the image on the display screen. The color film area of the color film unit 4 of each display pixel located at the edge area can be smaller than the color film area of the color film unit 4 of the first type of display pixels to ensure that the display brightness at the edge area is lower than the display brightness of the first type of display pixels.

An electronic device includes a body and a display screen as described above arranged on the body. The electronic device can be any desktop device or a variety of mobile devices that require a display screen, such as a mobile phone, a laptop, a tablet, or the like.

Consistent with the present disclosure, for the display screen having the curved edge 1, the color film area of the pixels in the area corresponding to the curved edge 1 can be different, and the area that is closest to curved edge 1 can have the smallest color film area. The color film area can be gradually increase as away from the curved edge 1. Thereby, the display screen can display any image, and the display effect corresponding to the curved edge 1 on the display screen can have a gradual effect, and the closer to the curved edge 1 corresponds to a darker display effect.

The embodiments disclosed herein are merely exemplary embodiments and are not intended to limit the present disclosure. The scope of the present disclosure is defined by the claims. Other applications, advantages, alternations, modifications, or equivalents to the disclosed embodiments are obvious to a person skilled in the art and are falling into the scope of the present disclosure.

What is claimed is:

1. A display screen comprising:
a plurality of display pixels, each display pixel including at least one color film unit, wherein:
the plurality of display pixels include a plurality of first-type display pixels and one or more second-type display pixels; and
a color film area of the color film unit of a second-type display pixel is different from a color film area of the color film unit of a first-type display pixel.

2. The display screen according to claim 1, wherein:
at least a portion of an edge of the display screen has a curved shape;
display pixels corresponding to the curved edge of the display screen among the plurality of display pixels are the second-type display pixels; and
a display effect of the second type of display pixels is different from a display effect of the first type of display pixels.

3. The display screen according to claim 2, wherein:
display pixels that are closest to the curved edge among the plurality of display pixels are the second type of display pixels.

4. The display screen according to claim 3, wherein:
the plurality of display pixels are arranged in an array;
the second type of display pixels include the display pixels having a shortest distance from the curve edge among at least one row of display pixels corresponding to the curved edge; or
the second type of display pixels include the display pixels having the shortest distance from the curved edge among at least one column of display pixels corresponding to the curved edge.

5. The display screen according to claim 4, wherein:
the color film area of the color film unit of the second type of display pixels is smaller than the color film area of the color film unit of the first type of display pixels.

6. The display screen according to claim 2, wherein:
the display pixels in an edge area corresponding to the curved edge among the plurality of display pixels are the second type of display pixels.

7. The display screen according to claim 6, wherein:
the plurality of display pixels are arranged in an array;
the display pixels in the edge area include:
a first display pixel including the display pixel having a shortest distance from the curved edge among at least one row of display pixels corresponding to the curved edge; and
a second display pixel including a display pixel adjacent to the first display pixel among at least one row of display pixels; or
the display pixels in the edge area include:
the first display pixel including the display pixel having the shortest distance from the curved edge among the at least one column of display pixels corresponding to the curved edge; and
the second display pixel including the display pixel adjacent to the first display pixel among the at least one column of display pixels.

8. The display screen according to claim 7, wherein:
the color film area of the color film unit of the first display pixel is smaller than the color film area of the color film unit of the second display pixel.

9. The display screen according to claim 7, wherein:
The color film area of the color film unit of any display pixel located at the edge area is smaller than the color film area of the color film unit of the first type of display pixels.

10. An electronic device comprising:
a body; and
a display screen including a plurality of display pixels, each display pixel including at least one color film unit,
wherein:
the plurality of display pixels include a plurality of first-type display pixels and one or more second-type display pixels; and
a color film area of the color film unit of a second-type display pixel is different from a color film area of the color film unit of a first-type display pixel.

11. The device according to claim 10, wherein:
at least a portion of an edge of the display screen has a curved shape;
display pixels corresponding to the curved edge of the display screen among the plurality of display pixels are the second-type display pixels; and
a display effect of the second type of display pixels is different from a display effect of the first type of display pixels.

12. The device according to claim 11, wherein:
display pixels that are closest to the curved edge among the plurality of display pixels are the second type of display pixels.

13. The device according to claim 12, wherein:
the plurality of display pixels are arranged in an array;
the second type of display pixels include the display pixels having a shortest distance from the curve edge among at least one row of display pixels corresponding to the curved edge; or
the second type of display pixels include the display pixels having the shortest distance from the curved edge among at least one column of display pixels corresponding to the curved edge.

14. The device according to claim 13, wherein:
the color film area of the color film unit of the second type of display pixels is smaller than the color film area of the color film unit of the first type of display pixels.

15. The device according to claim 11, wherein:
the display pixels in an edge area corresponding to the curved edge among the plurality of display pixels are the second type of display pixels.

16. The device according to claim 15, wherein:
the plurality of display pixels are arranged in an array;
the display pixels in the edge area include:
a first display pixel including the display pixel having a shortest distance from the curved edge among at least one row of display pixels corresponding to the curved edge; and
a second display pixel including a display pixel adjacent to the first display pixel among at least one row of display pixels; or
the display pixels in the edge area include:
the first display pixel including the display pixel having the shortest distance from the curved edge among the at least one column of display pixels corresponding to the curved edge; and
the second display pixel including the display pixel adjacent to the first display pixel among the at least one column of display pixels.

17. The device according to claim 16, wherein:
the color film area of the color film unit of the first display pixel is smaller than the color film area of the color film unit of the second display pixel.

18. The device according to claim 16, wherein:
The color film area of the color film unit of any display pixel located at the edge area is smaller than the color film area of the color film unit of the first type of display pixels.
